(19) United States
(12) Patent Application Publication
(10) Pub. No.: US 2010/0167531 A1
(43) Pub. Date: Jul. 1, 2010

(54) SEMICONDUCTOR DEVICE AND METHOD FOR MANUFACTURING THE SAME

(76) Inventor: Jeong-Ho Park, Icheon-si (KR)

Correspondence Address: SHERR & VAUGHN, PLLC, 620 HERNDON PARKWAY, SUITE 320, HERNDON, VA, 20170, US

(21) Appl. No.: 12/643,913

(22) Filed: Dec. 21, 2009

(30) Foreign Application Priority Data
Dec. 30, 2008 (KR) 10-2008-0136324

(51) Int. Cl. H01L 21/768

(52) U.S. Cl. 438/653; 438/669; 257/E21.584; 257/E21.582

(57) ABSTRACT

A semiconductor device and a method for manufacturing the same includes sequentially laminating a first dielectric film, an etch-blocking film and a second dielectric film on and/or over a semiconductor substrate, forming a photosensitive film mask to open a trench region in the second dielectric film, etching the second dielectric film using the photosensitive film mask as an etching mask until the etch-blocking film is exposed to form the trench, and then forming a copper metal layer in the trench at uniform thickness.

The present application claims priority under 35 U.S.C. §119 to Korean Patent Application No. 10-2008-0136324 (filed on Dec. 30, 2008), which is hereby incorporated by reference in its entirety.

### BACKGROUND

In semiconductor integrated circuit (IC) device technologies, a line technology refers to a technology to form lines to connect circuits in an IC device, provide a power source and transfer signals. Aluminum has been used as a line material for IC devices. However, high-integration and operation-rate increase in semiconductor IC devices cause a significant decrease in line width, an increase in line and contact resistance, and other problems such as signal delay, power loss and electromigration (EM).

A great deal of research has been conducted in association with copper lines. For example, copper lines and low-K dielectrics are generally utilized in 0.13 μm logic devices and copper lines are increasingly used for highly integrated memory products. Copper has a lower resistance (about 62%) than aluminum and has a high resistance to electromigration (EM), thus imparting superior reliability to high-integration and high-speed devices. In addition, copper exhibits superior electroplating properties and has a high yield, as compared to aluminum under the same conditions. Meanwhile, since copper, unlike aluminum, is unsuitable for dry-etching, copper lines are generally formed by a double damascene process to form a damascene structure comprising a trench and a hole on an interlayer dielectric film.

FIG. 1 is a sectional view illustrating a semiconductor device. As illustrated in example FIG. 1, the semiconductor device includes semiconductor substrate 10, multi-layered dielectric film 12 arranged thereon and/or thereover, metal layers 14A, 14B, 16A and 16B embedded in multi-layered dielectric film 12 and nitride film 18. In the case of semiconductor devices fabricated by a general damascene process, a copper metal layer formed by chemical mechanical polishing (CMP), a wafer center (WC) and a wafer edge (WE) are non-uniform in thickness 20. For example, as illustrated in FIG. 1, there is a difference (d) in thickness between copper metal layers 14A and 16A present in the WC, and copper metal layers 16B and 16B present in the WE. This difference (d) affects uniformity of sheet resistance (Rs), thus disadvantageously causing problems associated with yield.

### SUMMARY

Embodiments are related to a semiconductor device and a method for manufacturing the same that includes a copper metal layer.

Embodiments are related to a semiconductor device and a method for manufacturing the same having a metal layer embedded in a dielectric film at a uniform thickness on and/or over the overall surface of a wafer.

In accordance with embodiments, a method for manufacturing a semiconductor device that can include at least one of the following: sequentially laminating a first dielectric film, an etch-blocking film and a second dielectric film on and/or over a semiconductor substrate, forming a photosensitive film mask to open or otherwise expose a trench region in the second dielectric film, etching the second dielectric film using the photosensitive film mask as an etching mask until the etch-blocking film is exposed to form the trench, forming a copper metal layer on and/or over the second dielectric film while embedding the trench, and then polishing the copper metal layer until the second dielectric film is etched to allow the copper metal layer to remain only inside the trench.

In accordance with embodiments, a method for manufacturing a semiconductor device can include at least one of the following: sequentially laminating a first dielectric film, a second dielectric film and a polish-blocking film on and/or over a semiconductor substrate; forming a photosensitive film mask to open or otherwise expose a trench region in the polish-blocking film; etching the second dielectric film and the polish-blocking film using the photosensitive film mask as an etching mask to form the trench; forming a copper metal layer on and/or over the polish-blocking film while embedding the trench; and then polishing the copper metal layer until the uppermost surface of the polish-blocking film is etched to allow the copper metal layer to remain only inside the trench.

In accordance with embodiments, a semiconductor device can include at least one of the following: a first dielectric film, an etch-blocking film and a second dielectric film laminated on and/or over a semiconductor substrate in this order, and a copper metal layer embedded in a trench formed by etching the second dielectric film up to the etch-blocking film.

In accordance with embodiments, a semiconductor device can include at least one of the following: a first dielectric film, a second dielectric film and a polish-blocking film sequentially laminated on and/or over a semiconductor substrate in this order, and a copper metal layer embedded in a trench formed by etching the second dielectric film and the polish-blocking film up to the first dielectric film.

### DRAWINGS

FIG. 1 illustrates a semiconductor device.

FIGS. 2 to 5 illustrate a semiconductor device and a method for manufacturing a semiconductor device, in accordance with embodiments.

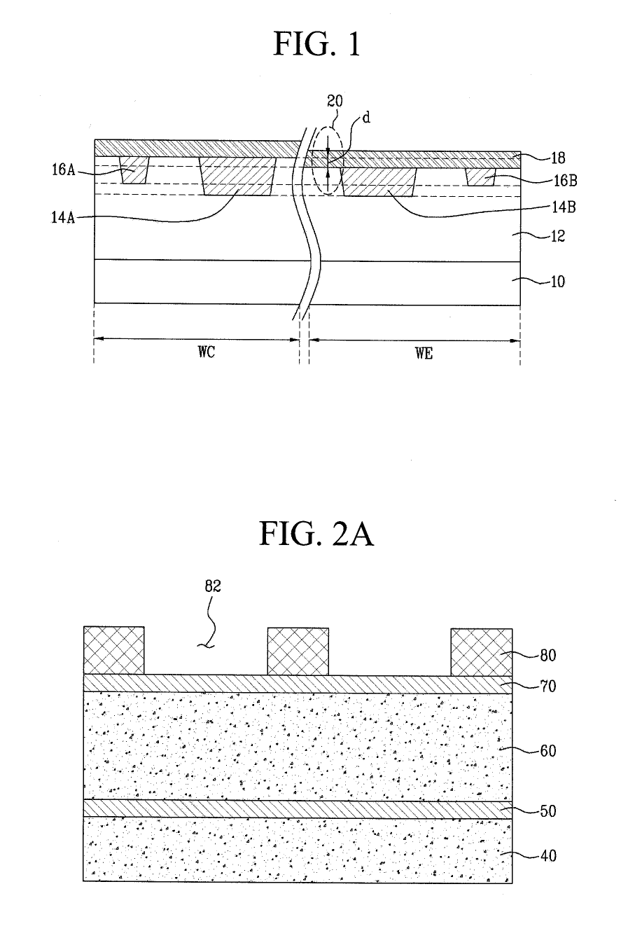

### DESCRIPTION

Hereinafter, a method for manufacturing a semiconductor device in accordance with embodiments will be described with reference to the annexed drawings. The same or similar elements are denoted by the same reference numerals.

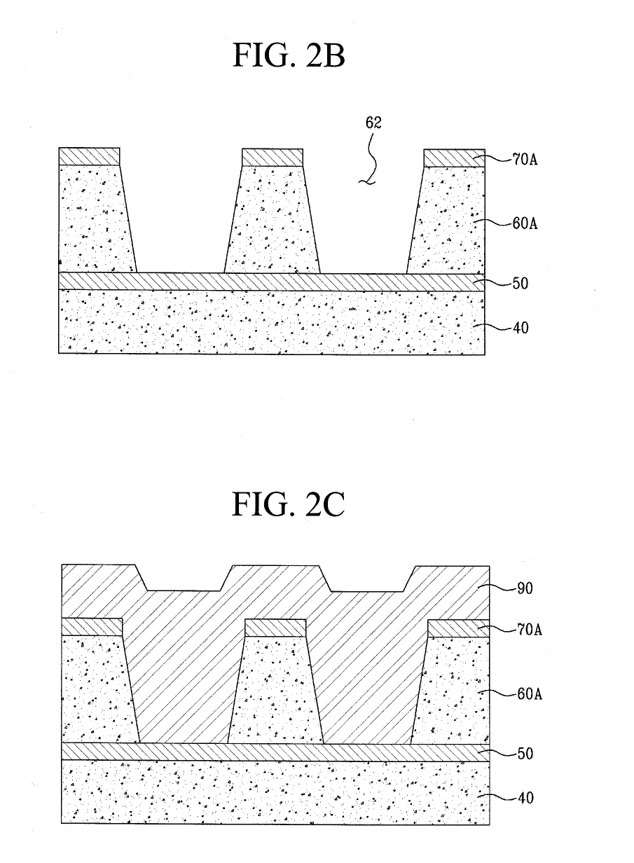

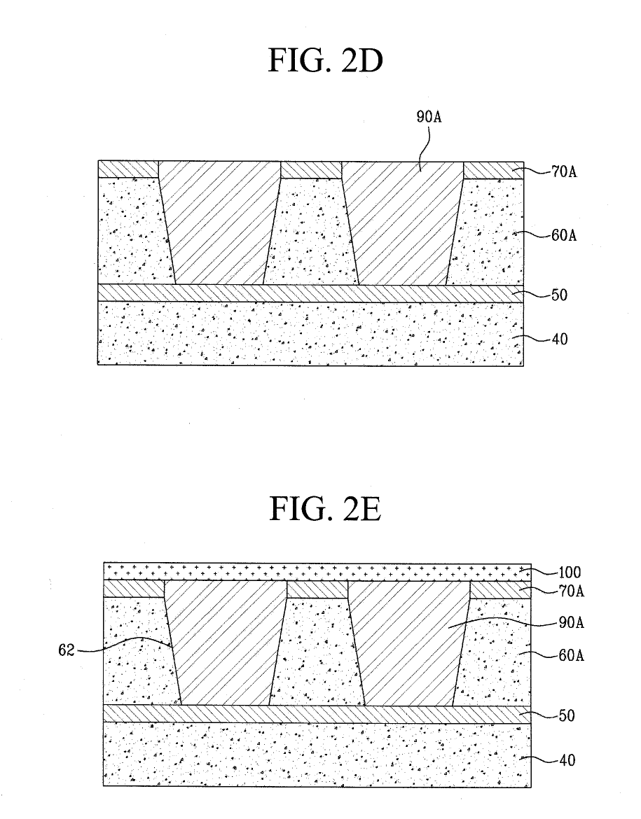

Example FIGS. 2A to 2E are sectional process views illustrating a method for manufacturing a semiconductor device, in accordance with embodiments.

As illustrated in example FIG. 2A, first dielectric film 40, etch-blocking film 50, second dielectric film 60 and polish-blocking film 70 are sequentially laminated on and/or over a semiconductor substrate. First dielectric film 40 and second dielectric film 60 may be composed of fluorine-doped silicon glass (FSG) or silicon oxycarbide (SiOC) films having a low-dielectric constant (e.g., about 3.5). In addition, first dielectric film 40 and second dielectric film 60 may be composed as porous dielectric films. Etch-blocking film 50 may be composed of a nitride film having a thickness in a range between 200 Å to 800 Å, but preferably 300 Å. In addition, polish-blocking film 50 may be composed of a nitride or SiC film having a thickness in a range between 300 Å to 1,500 Å.

For example, where etch-blocking film 50 or polish-blocking film 50 is a silicon nitride film, the silicon nitride film may be formed by a method such as plasma enhanced chemical vapor deposition (PECVD). In this case, a silane gas such as SiH₄ or Si₂H₆ is used as a silicon source gas. The silicon nitride film may be formed using an organic silane gas. Nitrogen or ammonia may be used as a nitrogen source gas together with the silicon source gas. Hot-wall low pressure chemical vapor deposition (LPCVD) as well as PECVD may be used to form the nitride film. The use of LPCVD for the formation of the silicon nitride film enables realization of uniform surface flatness and a homogeneous silicon nitride film. Then, photosensitive film mask 80 is formed on and/or over polish-blocking film 70 by a photolithographic process to expose trench region 82 and cover the remaining region.

As illustrated in example FIG. 2B, second dielectric film 60 and polish-blocking film 70 are then dry-etched using photosensitive film mask 80 as an etching mask until the uppermost surface of etch-blocking film 50 is exposed to thereby form trench 62. After the formation of trench 62, photosensitive film mask 80 is removed by ashing. The depth of trench 62 can be formed uniformly on and/or over the entire surface of a wafer since polish-blocking film 70 and second dielectric film 60 are etched using etch-blocking film 50.

As illustrated in example FIG. 2C, copper metal layer 90 is then formed on and/or over etched polish-blocking film 70A while embedding trench 62. Copper metal layer 90 may be formed by a method such as electrochemical plating (ECP). In order to form copper metal layer 90, a seed layer is first applied. A copper seed layer may be formed by physical vapor deposition (PVD). The copper seed layer serves as an electrode in the ECP process of forming copper metal layer 90, and transfers electric current from an anode arranged on the wafer edge to a cathode arranged on the wafer center. This current generates copper ions in a copper-electroplating solution to realize copper plating.

As illustrated in example FIG. 2D, the copper metal layer 90 is then polished by chemical mechanical polishing (CMP) until the uppermost surface of etched polish-blocking film 70A is exposed to allow copper metal layer 90A to remain only inside trench 62. The use of polish-blocking film 70 for polishing copper metal layer 90 enables formation of metal layer 90A having a uniform height over the entire surface of the wafer.

As illustrated in example FIG. 2E, diffusion-blocking film 100 is then formed on and/or over the polished resulting structure, i.e., copper metal layer 90A embedded in the etched polish-blocking film 70A and trench 62. In accordance with embodiments, diffusion-blocking film 100 may be composed of nitride, SiC, or titanium nitride (TiN), tantalum nitride (TaN), tantalum (Ta), or a combination thereof. For example, diffusion-blocking film 100 may have a thickness in a range between 500 Å to 1,500 Å.

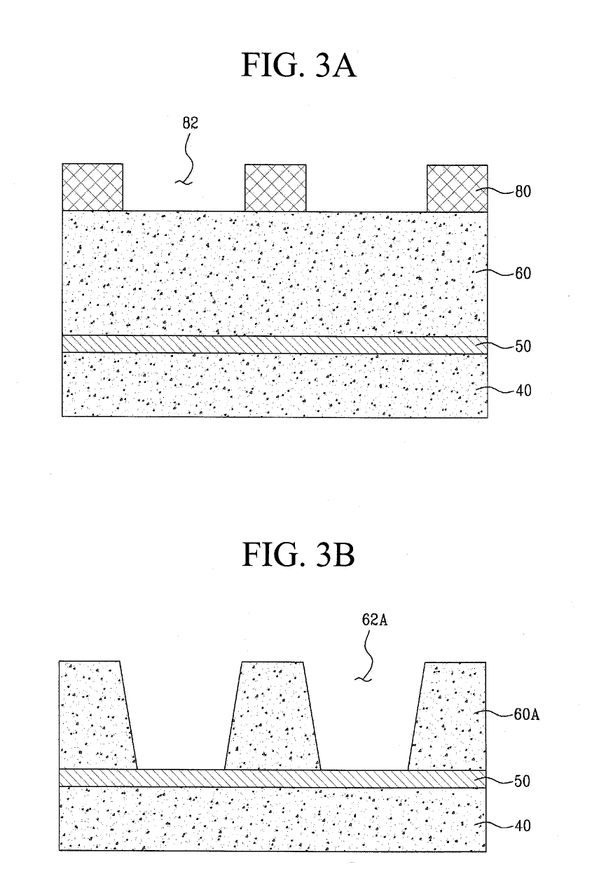

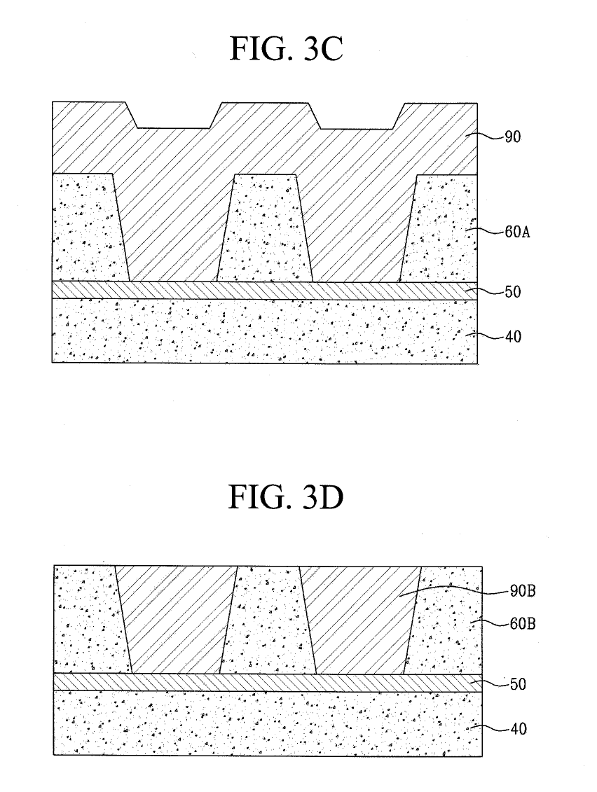

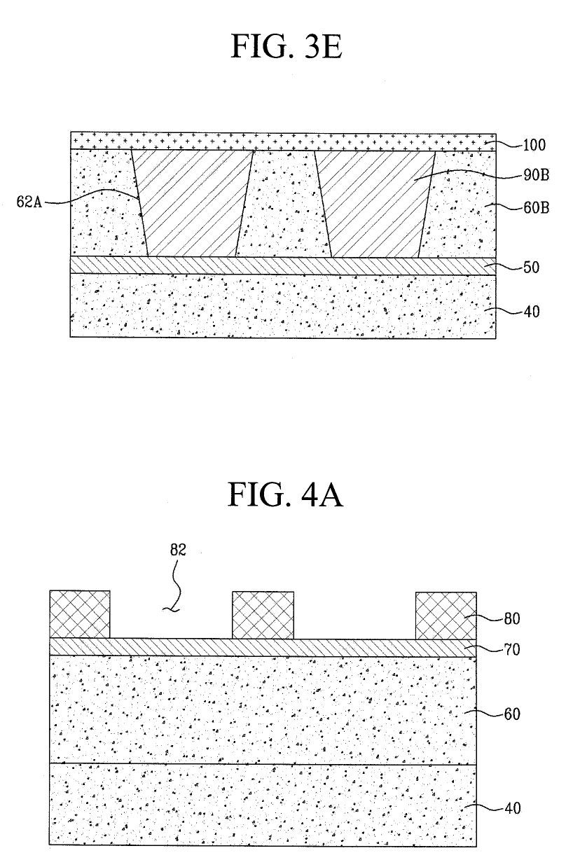

Example FIGS. 3A to 3E are sectional process views illustrating a method for manufacturing a semiconductor device, in accordance with embodiments.

As illustrated in example FIG. 3A, first dielectric film 40, etch-blocking film 50 and second dielectric film 60 are sequentially laminated on and/or over a semiconductor substrate. Photosensitive film mask 80 is then formed on and/or over second dielectric film 60 by a photolithographic process to open trench region 82 and cover the remaining region.

As illustrated in example FIG. 3B, second dielectric film 60 is then dry-etched using photosensitive film mask 80 as an etching mask until the uppermost surface of etch-blocking film 50 is exposed to thereby form trench 62A. There may be a difference in size between trench 62 illustrated in example FIG. 2B which is formed by etching second dielectric film 60 and polish-blocking film 70 and trench 62A illustrated in example FIG. 3B which is formed by etching only second dielectric film 60. After the formation of trench 62A, photosensitive film mask 80 is removed by ashing. The depth of trench 62A can be uniformly formed over the entire surface of a wafer since second dielectric film 60 is etched using etch-blocking film 50.

As illustrated in example FIG. 3C, copper metal layer 90 is then formed on and/or over etched second dielectric film 60B while embedding trench 62A.

As illustrated in example FIG. 3D, copper metal layer 90 is then polished by chemical mechanical polishing (CMP) until the uppermost surface of etched second dielectric film 60B is exposed to allow copper metal layer 90B to remain only inside trench 62A.

As illustrated in example FIG. 3E, diffusion-blocking film 100 is then formed on and/or over the polished resulting structure, i.e., copper metal layer 90B embedded in etched second dielectric film 60B and trench 62A which are exposed by the polishing process.

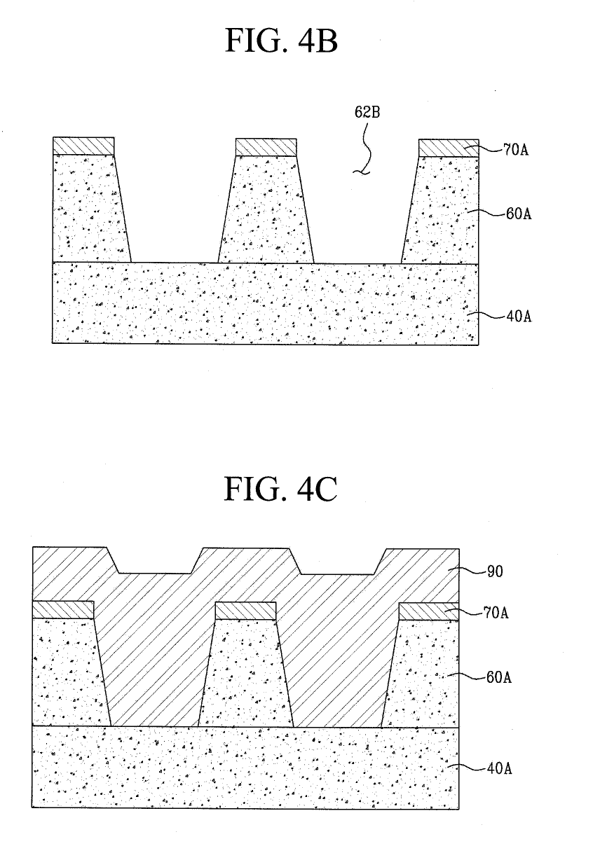

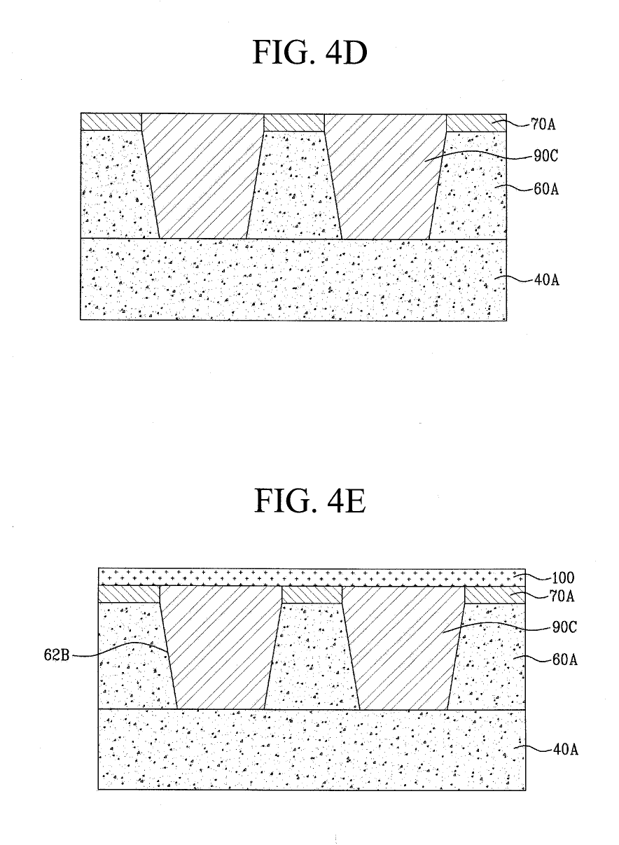

Example FIGS. 4A to 4E are sectional process views illustrating a method for manufacturing a semiconductor device, in accordance with embodiments.

As illustrated in example FIG. 4A, first dielectric film 40, second dielectric film 60 and polish-blocking film 70 are sequentially laminated on and/or over a semiconductor substrate. Photosensitive film mask 80 is then formed on and/or over polish-blocking film 70 by a photolithographic process to open trench region 82 and to cover the remaining region.

As illustrated in example 4B, second dielectric film 60 and polish-blocking film 70 are then dry-etched using photosensitive film mask 80 as an etching mask to form trench 62B. After the formation of trench 62B, photosensitive film mask 80 is removed by aching. There may be a difference in size between trench 62 illustrated in example FIG. 2B, which is formed by etching second dielectric film 60 and polish-blocking film 70, and trench 62A illustrated in example FIG. 4B, which is formed by etching second dielectric film 60 and polish-blocking film 70 without using etch-blocking film 50. In addition, first dielectric 40 not affected by the process of forming trench 62 using etch-blocking film 50 illustrated in example FIG. 2B may differ from first dielectric 40A which may be affected by the process for forming trench 62B without using etch-blocking film 50 illustrated in example FIG. 4B.

As illustrated in example FIG. 4C, copper metal layer 90 is then formed on and/or over etched polish-blocking film 70A while embedding trench 62B.

As illustrated in example FIG. 4D, copper metal layer 90 is then polished by chemical mechanical polishing (CMP), until the uppermost surface of etched polish-blocking film 70A is exposed to allow copper metal layer 90C to remain only inside trench 62B. The use of polish-blocking film 70 for polishing copper metal layer 90 enables formation of metal layer 90C having a uniform height over the overall surface of the wafer.

As illustrated in example FIG. 4E, diffusion-blocking film 100 is then formed on and/or over the polished resulting structure, i.e., copper metal layer 90C embedded in etched polish-blocking film 70A and trench 62.

In accordance with embodiments, first dielectric film 40 is arranged in the form of a monolayer between a semiconductor substrate and etch-blocking film 50. Second dielectric film 60 is arranged in the form of a monolayer between etch-blocking film 50 and polish-blocking film 70. However, embodiments are not limited to these constitutions. Meaning, a plurality of dielectric films including first dielectric film 40 may be arranged between the semiconductor substrate and etch-blocking film 50, and a plurality of dielectric films including second dielectric film 60 may be arranged between etch-blocking film 50 and polish-blocking film 70.

As illustrated in example FIG. 2E, first dielectric film 40, etch-blocking film 50, second dielectric film 60A and polish-blocking film 70A are laminated on and/or over the semiconductor substrate in this order. In addition, copper metal layer 90A is embedded in trench 62 formed by etching second dielectric film 60A and polish-blocking film 70 up to the uppermost surface of etch-blocking film 50.

As illustrated in example FIG. 3E, first dielectric film 40, etch-blocking film 50 and the second dielectric film 60B are laminated on and/or over the semiconductor substrate in this order. In addition, copper metal layer 90B is embedded in trench 62A formed by etching second dielectric film 60 up to the uppermost surface of etch-blocking film 50.

As illustrated in example FIG. 4E, first dielectric film 40A, second dielectric film 60A and polish-blocking film 70A are laminated on and/or over the semiconductor substrate in this order. In addition, copper metal layer 90C is embedded in trench 62B formed by etching second dielectric film 60 and polish-blocking film 70 up to the uppermost surface of first dielectric film 40.

In the semiconductor device illustrated in example FIGS. 2E and 4E, diffusion-blocking film 100 is arranged on and/or copper metal layers 90A and 90C and polish-blocking film 70A. In the semiconductor device illustrated in example FIG. 3E, diffusion-blocking film 100 is arranged on and/or copper metal layer 90B and second dielectric film 60B. In addition, copper metal layer 90 is embedded in only trench 62, 62A or 62B as illustrated above. However, embodiments are not limited to these constitutions. Meaning, embodiments may be applied to any case where etching and polishing processes are performed to embed copper metal layer 90A, 90B or 90C in a trench. For example, in the case of double damascene, vias as well as trenches are formed in the dielectric layer and the copper metal layers are embedded in the vias and the trenches. In this case, in the process of etching the dielectric layer to form the trenches and vias, etch-blocking layer 50 may be used to block the etching. In addition, polish-blocking film 70 may be used, when the copper metal layers embedded in the trenches and vias are polished to allow the copper metal layers to remain only in the trenches and vias.

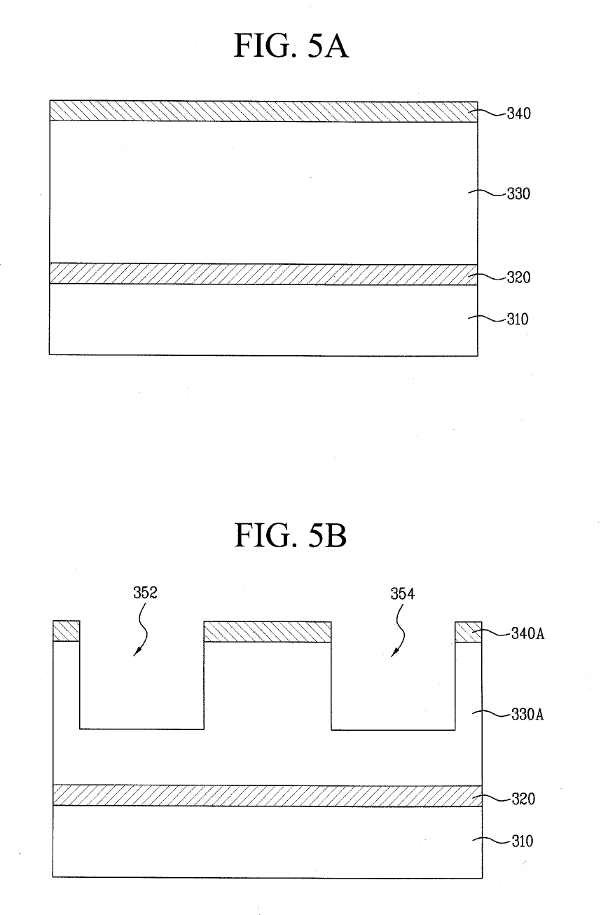

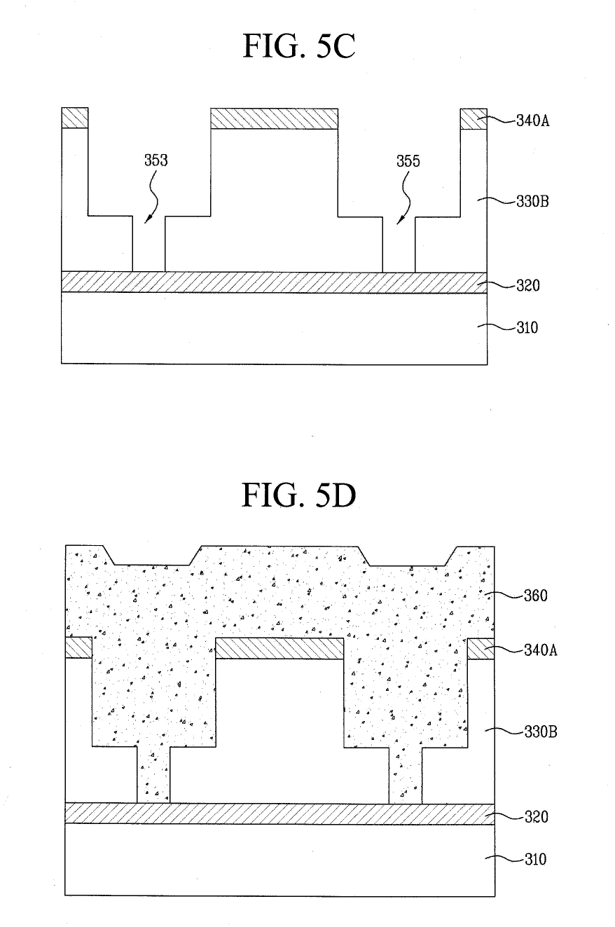

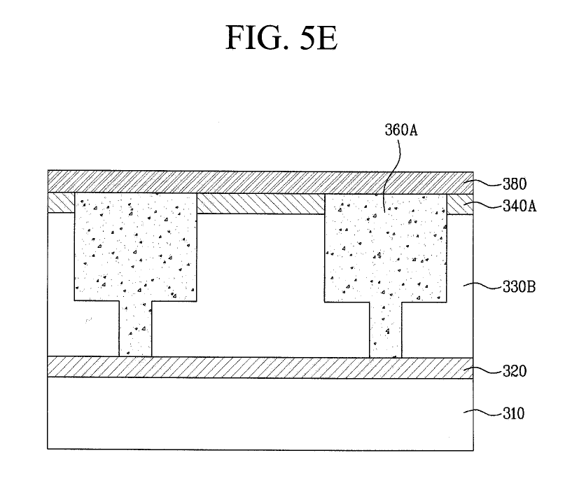

Example FIGS. 5A to 5E are sectional process views illustrating a method for manufacturing a semiconductor device, in accordance with embodiments.

As illustrated in example FIG. 5A, first dielectric film 310, etch-blocking film 320, second dielectric film 330 and polish-blocking film 340 are sequentially laminated on and/or a semiconductor substrate. First dielectric film 310, etch-blocking film 320, second dielectric film 330 and polish-blocking film 340 correspond to first dielectric film 40, etch-blocking film 50, second dielectric film 60 and polish-blocking film 70 illustrated in example FIG. 2A, respectively, and the two corresponding elements have identical properties and a detailed explanation thereof will be omitted.

As illustrated in example FIG. 5B, a portion of polish-blocking film 340 and second dielectric film 330 is then selectively etched to form first trench 352 and second trench 354 that do not expose etch-blocking film 320.

As illustrated in example FIG. 5C, second dielectric film 330A present under first trench 352 and second trench 354 is then partially etched, to form first via hole 353 and second via hole 355 exposing etch-blocking film 320. In the process of reactive ion etching (RIE) to etch first via hole 353 and second via hole 355, plasma may be heterogeneously distributed on the wafer center and edge, thus causing second dielectric film 330A to be non-uniformly etched. However, since an etching rate of etch-blocking layer 320 is much lower than that of second dielectric film 330A, etch uniformity of first via hole 353 and second via hole 355 can be enhanced. Meaning, first via hole 353 and second via hole 355 can be formed having a uniform thickness at the wafer center and edge.

As illustrated in example FIG. 5D, a metal layer 360 composed of copper is then formed on and/or over the entire surface of second dielectric film 330B and polish-blocking film 340A such that the first trench 352, second trench 354, first via hole 353 and second via hole 355 are embedded. The formation of metal layer 360 is carried out in the same manner as in formation of metal layer 90 and a detailed explanation thereof is omitted.

As illustrated in example FIG. 5E, metal layer 360 is then polished by CMP to form metal layer 360A embedded only in first trench 352, second trench 354, first via hole 353 and second via hole 355. The CMP is carried out until polish-blocking film 340 is exposed. Polish-blocking film 340 serves as a CMP-blocking film to stop the polishing process. CMP uniformity in the wafer center and edge can be enhanced since a polishing level of polish-blocking film 340A is much smaller than that of metal layer 360. Then, diffusion-blocking film 380 may be formed on and/or over polish-blocking film 340A. Diffusion-blocking film 380 has the same properties as diffusion-blocking film 100 as illustrated in example FIG. 2E, and a detailed explanation thereof is omitted.

As apparent from the fore-going, embodiments provide a semiconductor device and a method for manufacturing the same such that an etch-blocking film is interposed between dielectric films in which a copper metal layer is formed, thus allowing the dielectric films to be uniformly etched. For this reason, the bottom portions of the metal layer are flush with one another on and/or over the wafer. In addition, the semiconductor device further includes a polish-blocking film to maintain a polishing level of the metal layer, thus allowing the uppermost surface portions of the metal layer to be coplanar with one another over the wafer, and thereby prevent the problem of non-uniform thickness of the metal layer at the wafer center and edge. As a result, metal resistance uniformity and yield can be enhanced.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
sequentially laminating a first dielectric film, an etch-blocking film and a second dielectric film over a semiconductor substrate;
forming a photosensitive film mask over the second dielectric film to expose a trench region in the on the second dielectric film;
forming a trench in the on the second dielectric film by etching the second dielectric film using the photosensitive film mask as an etching mask;
forming a copper metal layer over the second dielectric film and embedding the trench; and
polishing the copper metal layer until the second dielectric film is etched such that the copper metal layer remains only in the trench.

2. The method of claim 1, wherein the trench exposes the etch-blocking film.

3. The method of claim 1, further comprising forming a polish-blocking film over the second dielectric film.

4. The method of claim 3, wherein the polish-blocking film comprises a nitride film.

5. The method of claim 3, wherein the polish-blocking film comprises an SiC film.

6. The method of claim 3, wherein the photosensitive film mask is formed over the polish-blocking film.

7. The method of claim 6, wherein the polish-blocking film is etched when forming the trench;

8. The method of claim 7, wherein the copper metal layer is formed over the polish-blocking film while embedding the trench; and

9. The method of claim 8, wherein polishing the copper metal layer is carried out until the polish-blocking film is exposed.

10. The method of claim 1, further comprising forming a diffusion-blocking film over the resulting structure obtained after polishing the copper metal layer.

11. The method of claim 10, wherein the diffusion-blocking film comprises a nitride film.

12. The method of claim 10, wherein the diffusion-blocking film comprises an SiC film.

13. The method of claim 10, wherein the diffusion-blocking film comprises one of titanium nitride (TiN), tantalum nitride (TaN), tantalum (Ta) or a combination thereof.

14. The method of claim 1, wherein the etch-blocking film comprises a nitride film.

15. A method comprising:
sequentially laminating a first dielectric film, a second dielectric film and a polish-blocking film over a semiconductor substrate;
forming a photosensitive film mask over the polish-blocking film to expose a trench region in the second dielectric film;
forming a trench by etching the second dielectric film and the polish-blocking film using the photosensitive film mask as an etching mask;
forming a copper metal layer over the polish-blocking film and embedding the trench; and then
polishing the copper metal layer until the top of the polish-blocking film is etched to allow the copper metal layer to remain only in the trench.

16. The method of claim 15, further comprising forming a diffusion-blocking film over the resulting structure obtained after polishing the copper metal layer.

17. The method of claim 16, wherein the diffusion-blocking film comprises one of a nitride film and an SiC film.

18. The method of claim 16, wherein the diffusion-blocking film comprises one of titanium nitride (TiN), tantalum nitride (TaN), tantalum (Ta) or a combination thereof.

19. The method of claim 15, wherein the polish-blocking film comprises one of a nitride film and an SiC film.

20. A method comprising:
sequentially laminating a first dielectric film, a second dielectric film and a polish-blocking film;
forming a photosensitive film mask over the polish-blocking film to expose a trench region in the second dielectric film;
forming a trench in the second dielectric film using the photosensitive film mask as an etching mask;
forming a copper metal layer over the polish-blocking film and embedding the trench; and then
polishing the copper metal layer to expose an uppermost surface of the polish-blocking film.
